(19) United States
(12) Patent Application Publication
(10) Pub. No.: US 2025/0323175 A1
(43) Pub. Date: Oct. 16, 2025

(54) SEMICONDUCTOR STRUCTURE AND MANUFACTURING METHOD THEREOF

(71) Applicant: United Microelectronics Corp., Hsinchu (TW)

(72) Inventors: Shin-Hung Li, Nantou County (TW); Shan-Shi Huang, Hsinchu City (TW); Chiu-Te Lee, Hsinchu County (TW)

(73) Assignee: United Microelectronics Corp., Hsinchu (TW)

(21) Appl. No.: 18/677,857

(22) Filed: May 29, 2024

(30) Foreign Application Priority Data
Apr. 10, 2024 (TW) 113113323

(51) Int. Cl. H01L 23/552; H01L 23/538; H10K 59/00

(52) U.S. Cl. CPC H01L 23/552; H01L 23/5384; H10K 59/00

(57) ABSTRACT

Provided are a semiconductor structure and a manufacturing method thereof. The semiconductor structure includes a substrate, a device structure layer, a dielectric layer, an organic light-emitting diode (OLED) device, a light shielding layer and a conductive via. The device structure layer is disposed on the substrate. The dielectric layer is disposed on the device structure layer. The OLED device is disposed on the dielectric layer. The light shielding layer is disposed between the dielectric layer and the device structure layer, or between the dielectric layer and the OLED device, or between the dielectric layer and the device structure layer and between the dielectric layer and the OLED device. The conductive via is disposed in the dielectric layer and the light shielding layer, and is electrically connected to the OLED device and the device structure layer.

### CROSS-REFERENCE TO RELATED APPLICATION

This application claims the priority benefit of Taiwan application serial no. 113113323, filed on Apr. 10, 2024. The entirety of the above-mentioned patent application is hereby incorporated by reference herein and made a part of this specification.

### BACKGROUND

### Technical Field

The present invention relates to a semiconductor structure and a manufacturing method thereof, and in particular to a semiconductor structure in which a light shielding layer is disposed between the organic light-emitting diode (OLED) device and the substrate and a manufacturing method thereof.

### Description of Related Art

In the current semiconductor process, before forming the OLED device, a dielectric layer is formed on the device structure layer on the substrate, and then the OLED device is formed on the dielectric layer. In addition, before forming the OLED device, a conductive via for electrically connecting the OLED device and the device structure layer is formed in the dielectric layer. For this kind of structure, when the light from the outside or the light from the OLED device enters the device structure layer, the performance of the device in the device structure layer may be affected.

### SUMMARY

The present invention provides a semiconductor structure and a manufacturing method thereof, in which a light shielding layer is formed between the OLED device and the substrate.

The semiconductor structure of the present invention includes a substrate, a device structure layer, a dielectric layer, an OLED device, a light shielding layer and a conductive via. The device structure layer is disposed on the substrate. The dielectric layer is disposed on the device structure layer. The OLED device is disposed on the dielectric layer. The light shielding layer is disposed between the dielectric layer and the device structure layer, or between the dielectric layer and the OLED device, or between the dielectric layer and the device structure layer and between the dielectric layer and the OLED device. The conductive via is disposed in the dielectric layer and the light shielding layer, and is electrically connected to the OLED device and the device structure layer.

In an embodiment of the semiconductor structure of the present invention, the light shielding layer is in contact with the conductive via.

In an embodiment of the semiconductor structure of the present invention, the light shielding layer is not in contact with the conductive via.

In an embodiment of the semiconductor structure of the present invention, a material of the light shielding layer includes a nitrogen-containing compound or amorphous silicon.

In an embodiment of the semiconductor structure of the present invention, the nitrogen-containing compound includes SiN, SiON or SiCN.

In an embodiment of the semiconductor structure of the present invention, the conductive via is connected to a bottom electrode of the OLED device.

In an embodiment of the semiconductor structure of the present invention, the conductive via is connected to a pad in the device structure layer.

The manufacturing method of the semiconductor structure of the present invention includes the following steps. A substrate is provided. A device structure layer is formed on the substrate. A dielectric layer is formed on the device structure layer. An OLED device is formed on the dielectric layer. A light shielding layer is formed, wherein the light shielding layer is formed between the dielectric layer and the device structure layer, or between the dielectric layer and the OLED device, or between the dielectric layer and the device structure layer and between the device structure layer and the OLED device. A conductive via is formed in the dielectric layer and the light shielding layer, wherein the conductive via is electrically connected to the OLED device and the device structure layer.

In an embodiment of the manufacturing method of the semiconductor structure of the present invention, the light shielding layer is in contact with the conductive via.

In an embodiment of the manufacturing method of the semiconductor structure of the present invention, the light shielding layer is not in contact with the conductive via.

In an embodiment of the manufacturing method of the semiconductor structure of the present invention, a material of the light shielding layer includes a nitrogen-containing compound or amorphous silicon.

In an embodiment of the manufacturing method of the semiconductor structure of the present invention, the nitrogen-containing compound includes SiN, SiON or SiCN.

In an embodiment of the manufacturing method of the semiconductor structure of the present invention, the conductive via is connected to a bottom electrode of the OLED device.

In an embodiment of the manufacturing method of the semiconductor structure of the present invention, the conductive via is connected to a pad in the device structure layer.

In an embodiment of the manufacturing method of the semiconductor structure of the present invention, the light shielding layer is formed after forming the device structure layer and before forming the dielectric layer.

In an embodiment of the manufacturing method of the semiconductor structure of the present invention, the conductive via is formed after forming the dielectric layer and before forming the OLED device, and the light shielding layer is formed after forming the dielectric layer and before forming the conductive via.

Based on the above, in the semiconductor structure of the embodiment of the present invention, since the light shielding layer is disposed between the OLED device and the device structure layer, the light from the outside or the light from the OLED device may be effectively blocked from entering the device structure layer to prevent the light from affecting the performance of the device in the device structure layer.

### BRIEF DESCRIPTION OF THE DRAWINGS

FIGS. 1A to 1C are schematic cross-sectional views of the manufacturing process of the semiconductor structure of the first embodiment of the present invention.

FIGS. 2A to 2B are schematic cross-sectional views of the manufacturing process of the semiconductor structure of the second embodiment of the present invention.

FIG. 3 is a schematic cross-sectional view of the semiconductor structure of the third embodiment of the present invention.

FIG. 4 is a schematic cross-sectional view of the semiconductor structure of the fourth embodiment of the present invention.

FIG. 5 is a schematic cross-sectional view of the semiconductor structure of the fifth embodiment of the present invention.

### DESCRIPTION OF THE EMBODIMENTS

The embodiments are listed below and described in detail with the accompanying drawings, but the provided embodiments are not intended to limit the scope of the present invention. In addition, the drawings are for illustration purposes only and are not drawn to original scale. In order to facilitate understanding, the same devices will be described with the same symbols in the following descriptions.

In the text, the terms mentioned in the text, such as “comprising”, “including”, “containing” and “having” are all open-ended terms, i.e., meaning “including but not limited to”.

When using terms such as “first” and “second” to describe elements, it is only used to distinguish the elements from each other, and does not limit the order or importance of the devices. Therefore, in some cases, the first element may also be called the second element, the second element may also be called the first element, and this is not beyond the scope of the present invention.

In addition, the directional terms, such as “on”, “above”, “under” and “below” mentioned in the text are only used to refer to the direction of the drawings, and are not used to limit the present invention. Therefore, it should be understood that “on” may be used interchangeably with “under”. When a device such as a layer or a film is placed “on” another device, the device may be placed directly on the other device, or an intermediate device may be present. On the other hand, when a device is placed “directly on” another device, there is no intermediate device between the two.

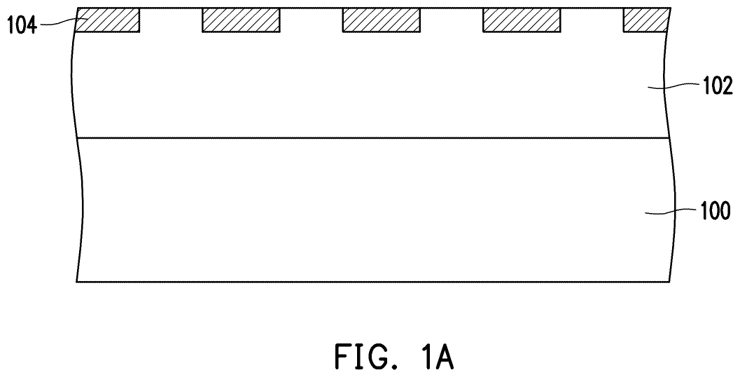

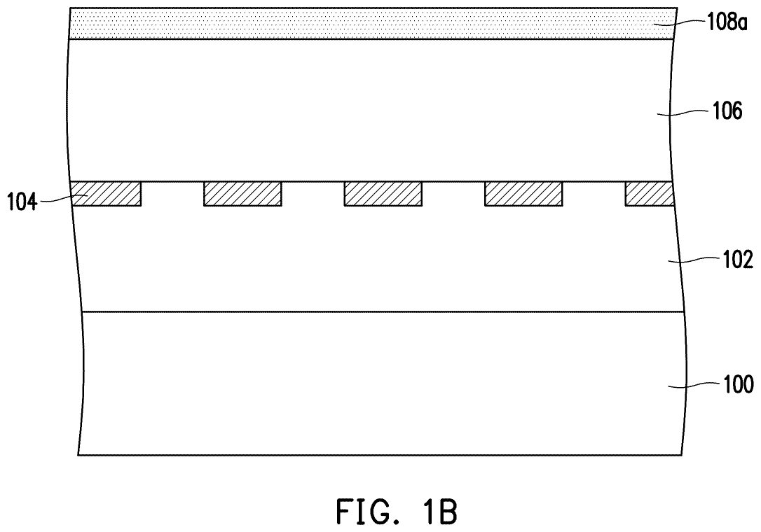

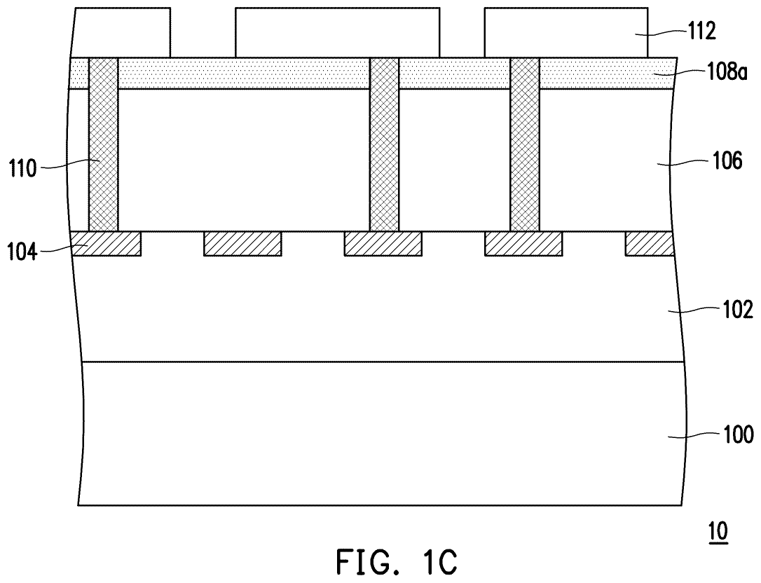

FIGS. 1A to 1C are schematic cross-sectional views of the manufacturing process of the semiconductor structure of the first embodiment of the present invention.

Referring to FIG. 1A, a substrate 100 is provided. In the present embodiment, the substrate 100 may be a silicon substrate, but the present invention is not limited thereto. Then, a device structure layer 102 is formed on the substrate 100. The device structure layer 102 may include various well-known semiconductor devices. For example, the device structure layer 102 may include a transistor formed at the surface of the substrate 100, an interconnect structure electrically connected to the transistor, and a dielectric layer covering the transistor and the interconnect structure, but the present invention is not limited thereto. Furthermore, in the present embodiment, the device structure layer 102 includes pads 104 exposed at the surface of the device structure layer 102. The pads 104 may be electrically connected to the above-mentioned various semiconductor devices, and may be used as terminals to connect to the external devices. In other embodiments, the device structure layer 102 may not include the pads 104, but may include a circuit pattern exposed at the surface of the device structure layer 102.

In FIG. 1A, for making the drawing clear, the various semiconductor devices in the device structure layer 102 are not shown, but only the pads 104 are shown. The detailed structure and forming method of the device structure layer 102 are well known to those skilled in the art and will not be described further here. In addition, in FIG. 1A, the number of the pads 104 is only exemplary, and the present invention is not limited thereto.

Referring to FIG. 1B, a dielectric layer 106 is formed on the device structure layer 102. In the present embodiment, the dielectric layer 106 is a silicon oxide layer. The dielectric layer 106 may be used as an inter-metal dielectric (IMD) layer in the semiconductor structure of the present embodiment. Then, a light shielding layer 108a is formed on the dielectric layer 106. In the present embodiment, the material of the light shielding layer 108a may be nitrogen-containing compound or amorphous silicon. The nitrogen-containing compound is, for example, SiN, SiON or SiCN. In addition, in the present embodiment, the light shielding layer 108a is a single layer, but the present invention is not limited thereto. In other embodiments, the light shielding layer 108a may be a composite layer composed of different material layers.

Referring to FIG. 1C, conductive vias 110 connected to the pads 104 are formed in the dielectric layer 106 and the light shielding layer 108a. In FIG. 1C, the number of the conductive vias 110 is only exemplary, and the present invention is not limited thereto. In the present embodiment, the forming method of the conductive vias 110 may include the following steps. Openings exposing the pads 104 are formed in the dielectric layer 106 and the light shielding layer 108a. Then, a conductive material is formed on the light shielding layer 108a and fills the openings. After that, the conductive material outside the openings is removed, and the conductive material in the openings forms the conductive vias 110. Therefore, in the present embodiment, the conductive vias 110 are exposed to the surface of the light shielding layer 108a, and the conductive vias 110 are in contact with the light shielding layer 108a.

After forming the conductive vias 110, an OLED device 112 is formed on the light shielding layer 108a. The OLED device 112 is connected to conductive vias 110. In the present embodiment, the conductive vias 110 are connected to the bottom electrode (not shown) of the OLED device 112, but the present invention is not limited thereto. In this way, the semiconductor structure 10 of the present embodiment is formed.

In the semiconductor structure 10 of the present embodiment, since the light shielding layer 108a is formed between the OLED device 112 and the device structure layer 102, the light from the outside or the light from the OLED device 112 may be effectively blocked from entering the device structure layer 102, so as to prevent the light from affecting the performance of the devices in the device structure layer 102.

In addition, in the present embodiment, after the dielectric layer 106 is formed, the light shielding layer 108a is directly formed on the dielectric layer 106, and after the light shielding layer 108a is formed, the OLED device 112 is formed on the light shielding layer 108a. Therefore, the process steps of the semiconductor structure 10 of the present embodiment are relatively simple, and no additional photomask is required.

In the semiconductor structure 10 of the first embodiment, the light shielding layer 108a is formed between the OLED device 112 and the dielectric layer 106, but the present invention is not limited thereto. In other embodiments, the light shielding layer 108a may be formed between device structure layer 102 and dielectric layer 106. This is explained in detail below.

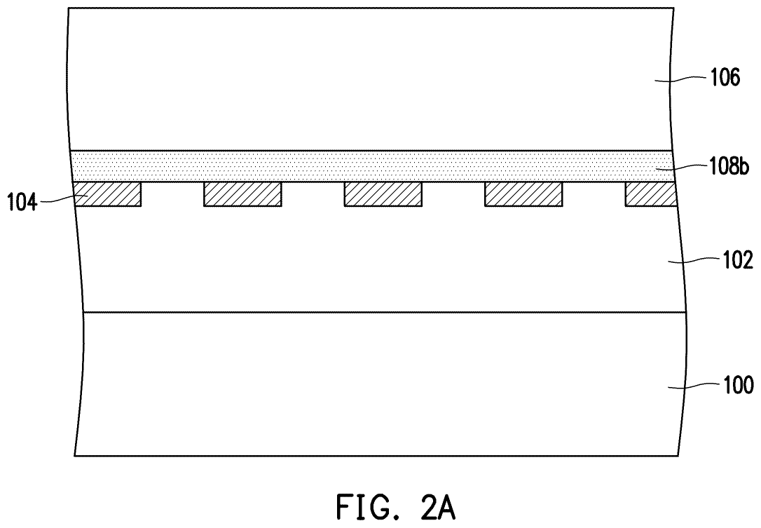

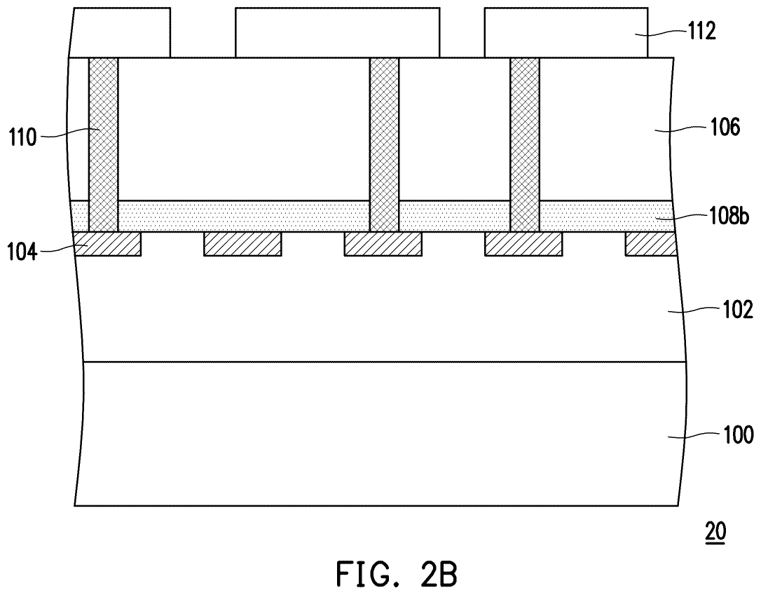

FIGS. 2A to 2B are schematic cross-sectional views of the manufacturing process of the semiconductor structure of the second embodiment of the present invention. In the present embodiment, the devices that are the same as those in the first embodiment will be represented by the same reference numbers and will not be described again.

Referring to FIG. 2A, after the steps described in FIG. 1A, a light shielding layer 108b is formed on the device structure layer 102. In the present embodiment, the material of the light shielding layer 108b may be nitrogen-containing compound or amorphous silicon. The nitrogen-containing compound is, for example, SiN, SiON or SiCN. In addition, in the present embodiment, the light shielding layer 108b is a single layer, but the present invention is not limited thereto. In other embodiments, the light shielding layer 108b may be a composite layer composed of different material layers. After that, the dielectric layer 106 is formed on the light shielding layer 108b.

Referring to FIG. 2B, the conductive vias 110 connected to the pads 104 is formed in the dielectric layer 106 and the light shielding layer 108b. After that, the OLED device 112 is formed on the dielectric layer 106. The OLED device 112 is connected to conductive vias 110. In this way, the semiconductor structure 20 of the present embodiment is formed.

In the semiconductor structure 20 of the present embodiment, since the light shielding layer 108b is formed between the dielectric layer 106 and the device structure layer 102, the light from the outside or the light from the OLED device 112 may be effectively blocked from entering the device structure layer 102, so as to prevent the light from affecting the performance of the devices in the device structure layer 102.

In addition, in the present embodiment, after the device structure layer 102 is formed, the light shielding layer 108b is directly formed on the device structure layer 102, and after the light shielding layer 108b is formed, the dielectric layer 106, the conductive via 110 and the OLED device 112 are formed. Therefore, the process steps of the semiconductor structure 20 of the present embodiment are relatively simple, and no additional photomask is required.

In the first embodiment, the light shielding layer 108a is formed between the OLED device 112 and the dielectric layer 106, while in the second embodiment, the light shielding layer 108b is formed between the dielectric layer 106 and the device structure layer 102. In other embodiments, the light shielding layer 108a and the light shielding layer 108b may be formed depending on actual needs.

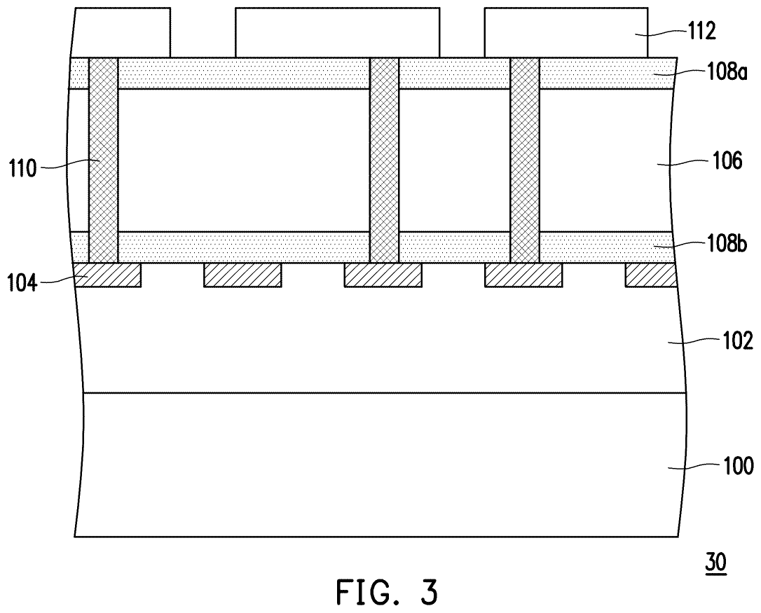

FIG. 3 is a schematic cross-sectional view of the semiconductor structure of the third embodiment of the present invention. In the present embodiment, the devices that are the same as those in the first and second embodiments will be represented by the same reference numbers and will not be described again.

Referring to FIG. 3, after the steps described in FIG. 1A, the light shielding layer 108b is formed on the device structure layer 102. In addition, after the dielectric layer 106 is formed, the light shielding layer 108a is formed on the dielectric layer 106. After that, the steps described in FIG. 1C are performed to form the conductive vias 110 connected to the pads 104 in the dielectric layer 106, the light shielding layer 108a and the light shielding layer 108b, and the OLED device 112 connected to the conductive vias 110 is formed. In this way, the semiconductor structure 30 of the present embodiment is formed.

In the semiconductor structure 30 of the present embodiment, since the light shielding layer 108a and the light shielding layer 108b are formed between the OLED device 112 and the device structure layer 102, the light from the outside or the light from the OLED device 112 may be effectively blocked from entering the device structure layer 102, so as to prevent the light from affecting the performance of the devices in the device structure layer 102.

In addition, in the present embodiment, after the device structure layer 102 is formed, the light shielding layer 108b is directly formed on the device structure layer 102, and after the dielectric layer 106 is formed, the light shielding layer 108a is directly formed on the dielectric layer 106. Therefore, the process steps of the semiconductor structure 30 of the present embodiment is relatively simple, and no additional photomask is required.

In each of the above embodiments, the light shielding layer 108a and the light shielding layer 108b are in contact with the conductive vias 110, but the present invention is not limited thereto. In other embodiments, the light shielding layer 108a and the light shielding layer 108b may not be in contact with the conductive vias 110 according to actual requirements.

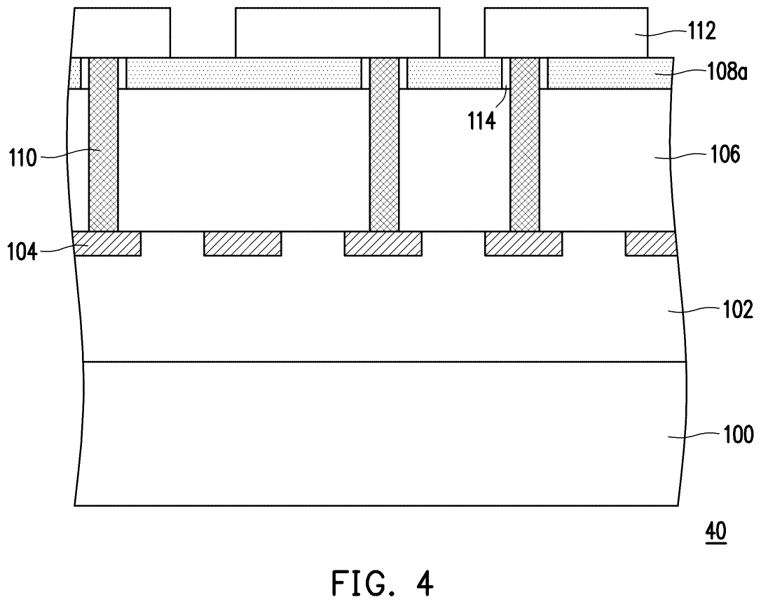

FIG. 4 is a schematic cross-sectional view of the semiconductor structure of the fourth embodiment of the present invention. In the present embodiment, the devices that are the same as those in the first embodiment will be represented by the same reference numbers and will not be described again.

Referring to FIG. 4, the difference between the semiconductor structure 40 of the present embodiment and the semiconductor structure 10 is that in the semiconductor structure 40, the light shielding layer 108a is not in contact with the conductive vias 110. In addition, a dielectric layer 114 is disposed between light shielding layer 108a and conductive vias 110. The material of dielectric layer 114 may be the same as or different from the dielectric layer 106.

In the present embodiment, since the dielectric layer 114 is disposed between the light shielding layer 108a and the conductive vias 110, the material of the light shielding layer 108a may be not only nitrogen-containing compound or amorphous silicon, but also metal, such as Al or Ag. When the material of the light shielding layer 108a is metal, the light shielding layer 108a must not be in contact with the OLED device 112 to avoid causing electrical problems.

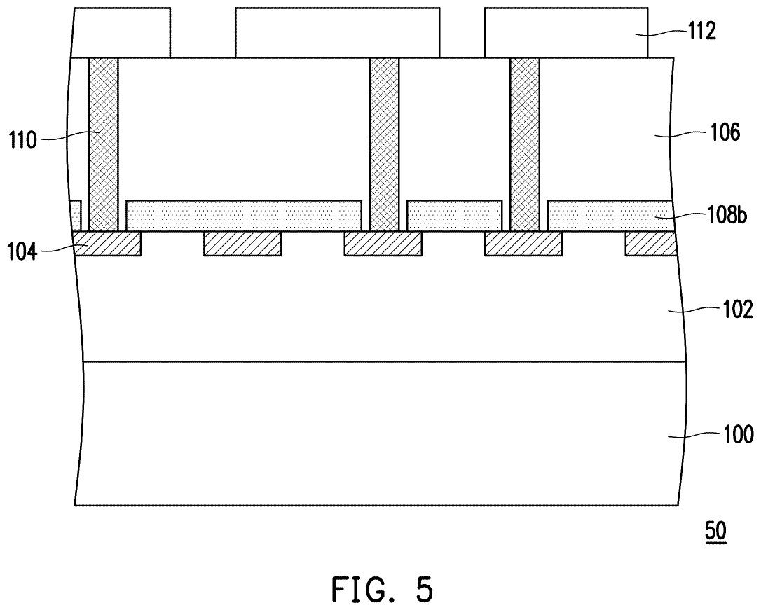

FIG. 5 is a schematic cross-sectional view of the semiconductor structure of the fifth embodiment of the present invention. In the present embodiment, the devices that are the same as those in the second embodiment will be represented by the same reference numbers and will not be described again.

Referring to FIG. 5, the difference between the semiconductor structure 50 of the present embodiment and the semiconductor structure 10 is that in the semiconductor structure 50, the light shielding layer 108b is not in contact with the conductive vias 110. In addition, the dielectric layer 106 may be further located between the light shielding layer 108b and the conductive vias 110.

In the present embodiment, since the dielectric layer 106 is disposed between the light shielding layer 108b and the conductive vias 110, the material of the light shielding layer 108b may be not only nitrogen-containing compound or amorphous silicon, but also metal, such as Al or Ag. When the material of the light shielding layer 108b is metal, the light shielding layer 108b must not be in contact with the pads to avoid causing electrical problems.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor structure, comprising:
a substrate;
a device structure layer, disposed on the substrate;
a dielectric layer, disposed on the device structure layer;
an organic light-emitting diode (OLED) device, disposed on the dielectric layer;
a light shielding layer, disposed between the dielectric layer and the device structure layer, or disposed between the dielectric layer and the OLED device, or disposed between the dielectric layer and the device structure layer and between the dielectric layer and the OLED device; and
a conductive via, disposed in the dielectric layer and the light shielding layer, and electrically connected to the OLED device and the device structure layer.

2. The semiconductor structure of claim 1, wherein the light shielding layer is in contact with the conductive via.

3. The semiconductor structure of claim 1, wherein the light shielding layer is not in contact with the conductive via.

4. The semiconductor structure of claim 1, wherein a material of the light shielding layer comprises a nitrogen-containing compound or amorphous silicon.

5. The semiconductor structure of claim 4, wherein the nitrogen-containing compound comprises SiN, SiON or SICN.

6. The semiconductor structure of claim 1, wherein the conductive via is connected to a bottom electrode of the OLED device.

7. The semiconductor structure of claim 1, wherein the conductive via is connected to a pad in the device structure layer.

8. A manufacturing method of a semiconductor structure, comprising:
providing a substrate;
forming a device structure layer on the substrate;
forming a dielectric layer on the device structure layer;
forming an organic light-emitting diode (OLED) device on the dielectric layer;
forming a light shielding layer, wherein the light shielding layer is formed between the dielectric layer and the device structure layer, or between the dielectric layer and the OLED device, or between the dielectric layer and the device structure layer and between the device structure layer and the OLED device; and
forming a conductive via in the dielectric layer and the light shielding layer, wherein the conductive via is electrically connected to the OLED device and the device structure layer.

9. The manufacturing method of claim 8, wherein the light shielding layer is in contact with the conductive via.

10. The manufacturing method of claim 8, wherein the light shielding layer is not in contact with the conductive via.

11. The manufacturing method of claim 8, wherein a material of the light shielding layer comprises a nitrogen-containing compound or amorphous silicon.

12. The manufacturing method of claim 11, wherein the nitrogen-containing compound comprises SiN, SiON or SiCN.

13. The manufacturing method of claim 8, wherein the conductive via is connected to a bottom electrode of the OLED device.

14. The manufacturing method of claim 8, wherein the conductive via is connected to a pad in the device structure layer.

15. The manufacturing method of claim 8, wherein the light shielding layer is formed after forming the device structure layer and before forming the dielectric layer.

16. The manufacturing method of claim 8, wherein the conductive via is formed after forming the dielectric layer and before forming the OLED device, and the light shielding layer is formed after forming the dielectric layer and before forming the conductive via.
